(19) United States
(12) Patent Application Publication
(10) Pub. No.: US 2020/0035887 A1
(43) Pub. Date: Jan. 30, 2020

(54) LIGHT-EMITTING DIODE DEVICE

(71) Applicant: Lextar Electronics Corporation, Hsinchu (TW)

(72) Inventor: Li-Tsung LIU, Hsinchu City (TW)

(21) Appl. No.: 16/233,119

(22) Filed: Dec. 27, 2018

(30) Foreign Application Priority Data
Jul. 25, 2018 (CN) 201810826120.5

(51) Int. Cl. H01L 33/62; H01L 33/36

(52) U.S. Cl. CPC H01L 33/62; H01L 33/32; H01L 33/36

(57) ABSTRACT

A light-emitting diode device includes a first-type semiconductor layer, a second-type semiconductor layer, a light-emitting layer, a current distribution layer and a high-dielectric-constant insulation layer. The light-emitting layer is located between the first-type and the second-type semiconductor layers. The current distribution layer is located above the second-type semiconductor layer. The high-dielectric-constant insulation layer is formed uniformly between the current distribution layer and the second-type semiconductor layer.

### CROSS-REFERENCE TO RELATED APPLICATION

This application claims priority to China Application Serial Number 201810826120.5, filed Jul. 25, 2018 which is herein incorporated by reference.

### BACKGROUND

### Field of Invention

The present disclosure relates to a light-emitting diode which emits light uniformly.

### Description of Related Art

In the current LED devices, an indium tin oxide transparent film is often used as a current diffusion layer. The indium tin oxide film has a relatively high sheet resistance (Rs), which makes it difficult to diffuse current over the surface of the LED chip, and thus restricts the light-emitting area such that the LED device cannot uniformly emit light from its entire surface.

In order to make the LEDs to have a luminous uniformity over the entire emitting surface, more metal electrodes are currently designed over the indium tin oxide film to uniformly disperse the electron flow over the entire emitting surface of the light-emitting diode chip. Adding the metal electrodes on the emitting surface can effectively improve the uniform dispersion of the electron flow to over the indium tin oxide film, but the opaque metal electrodes also cause a large number of shading problems and reliability problems.

### SUMMARY

In one or more embodiments, a light-emitting diode device includes a first-type semiconductor layer, a second-type semiconductor layer, a light-emitting layer, a current distribution layer and a high-dielectric-constant insulation layer. The light-emitting layer is located between the first-type and the second-type semiconductor layers. The current distribution layer is located above the second-type semiconductor layer. The high-dielectric-constant insulation layer is distributed uniformly between the current distribution layer and the second-type semiconductor layer.

In one or more embodiments, the high-dielectric-constant insulation layer has a dielectric constant greater than or equal to 4.

In one or more embodiments, the high-dielectric-constant insulation layer comprises Al₂O₃, BaTiO₃, TiO₂, HfO₂, La₂O₃ or Pr₂O₃.

In one or more embodiments, the light-emitting diode device further includes a metallic electrode in contact with the current distribution layer, and a section of the current distribution layer, with which the metallic electrode is aligned, does not have a current block material.

In one or more embodiments, the current distribution layer, the high-dielectric-constant insulation layer and the second-type semiconductor layer collectively form a capacitor when the current distribution layer is applied with an electric voltage smaller than a turn-on threshold voltage of the light-emitting layer.

In one or more embodiments, the light-emitting diode device further includes a metallic electrode in contact with the current distribution layer, and an electric current applied to the metallic electrode is in a nonlinear relationship with an electric voltage applied to the metallic electrode when the light-emitting diode device is in a light-emitting state.

In one or more embodiments, the light-emitting diode device further includes a metallic electrode in contact with the current distribution layer, and an electric current applied to the metallic electrode is in a curve relationship with an electric voltage applied to the metallic electrode when the light-emitting diode device is in a light-emitting state.

In one or more embodiments, a maximum difference of a light-emitting intensity output from the current distribution layer except the metallic electrode is smaller than 30%.

In one or more embodiments, the high-dielectric-constant insulation layer has a thickness less than 15 nanometers.

In one or more embodiments, the high-dielectric-constant insulation layer has a thickness ranging from 3 nanometers to 8 nanometers.

In sum, the light-emitting diode device of the present invention utilizes the current distribution mechanism achieved by the electron tunneling method. When the low bias voltage is applied, e.g., smaller than a turn-on threshold voltage of the light-emitting layer, electrons are accumulated to form a surface potential. When the high bias voltage is applied, e.g., greater than a turn-on threshold voltage of the light-emitting layer, full planar electrons form tunneling currents through the insulation layer into the semiconductor layers so as to excite light. This method can solve the uneven problem of current diffusion illuminating, and can also reduce the light-shield problems caused by the large areas of electrodes. This electron tunneling mechanism can be applied to grains of different sizes for the different insulation layers, and the different grain sizes only need to change the positional energy barrier condition to achieve the electron tunneling mechanism.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a cross-sectional view of a light-emitting diode device according to one embodiment of the present disclosure;

FIG. 2 illustrates a schematic view showing an operation principle of the light-emitting diode device of FIG. 1 at a low bias voltage;

FIG. 3 illustrates a schematic view showing an operation principle of the light-emitting diode device of FIG. 1 at a high bias voltage;

FIG. 4 illustrates a current-voltage diagram of the light-emitting diode device of FIG. 1 at a high bias voltage;

FIG. 5 illustrates a top view of an electrode of a conventional light-emitting diode device;

FIG. 6 illustrates a top view of an electrode of a light-emitting diode device according to one embodiment of the present disclosure; and

FIG. 7 illustrates a luminous intensity distribution diagram along a line 7-7′ of the light-emitting diode devices in FIGS. 5 and 6.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

Since the development of the light-emitting diodes, there has always been a problem of uneven distribution of electrons flowing through the electric field to the light-emitting region. Therefore, it is hard to achieve a uniform diffusion of current on the LED chip even with the design of adding large area of electrodes over the indium tin oxide film. The present invention is directed to an LED device that provides more uniform current spreading across the LED chip.

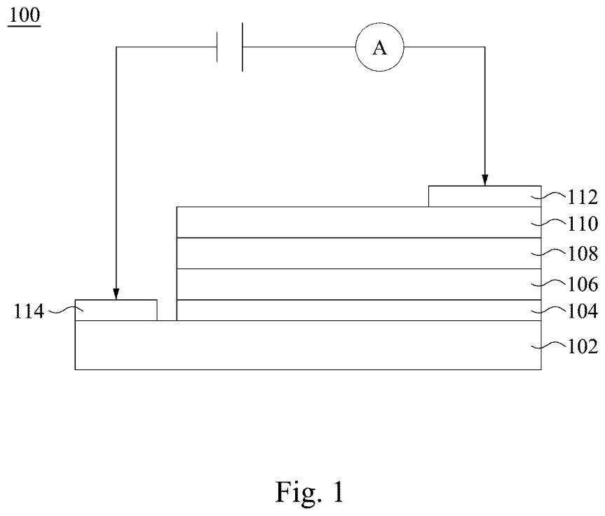

Reference is made to FIG. 1, which illustrates a cross-sectional view of a light-emitting diode device according to one embodiment of the present disclosure.

A light-emitting diode device 100 includes a first-type semiconductor layer 102 and a second-type semiconductor layer 106. A light-emitting layer 104 is formed between the first-type semiconductor layer 102 and the second-type semiconductor layer 106. A current distribution layer 110 is formed over and above the second-type semiconductor layer 106, and a high-dielectric-constant insulation layer 108 is formed uniformly, e.g., with a uniform thickness, between the current distribution layer 110 and the second-type semiconductor layer 106. A metallic electrode 112 is formed in contact with the current distribution layer 110, and another metallic electrode 114 is formed on an exposed portion, i.e., uncovered by the layers 104 and 106, of the first-type semiconductor layer 102.

In one or more embodiments, the first-type semiconductor layer 102 is an N-type GaN semiconductor layer, and the second-type semiconductor layer 106 is a P-type GaN semiconductor layer, but the first-type and second-type semiconductor layers 102 and 106 of the present invention are not limited thereto, and other known materials may be applicable.

In one or more embodiments, the light-emitting layer 104 located between the first-type and second-type semiconductor layers may be a multiple quantum well (MQW), but the structure of the light-emitting layer of the present invention is not limited thereto, and other known PN junction layers may be applicable.

In one or more embodiments, the current distribution layer 110 may be an indium tin oxide film, but not being limited thereto.

In one or more embodiments, the high-dielectric-constant insulation layer 108, formed uniformly between the current distribution layer 110 and the second-type semiconductor layer 106, may have a dielectric constant greater than or equal to four.

In one or more embodiments, the high-dielectric-constant insulation layer 108 may be, for example, Al₂O₃, BaTiO₃, TiO₂, HfO₂, La₂O₃ or Pr₂O₃, but not being limited thereto.

In this invention, the transmission mechanism of electrons passing through the high-dielectric-constant insulation layer 108 is an electron tunneling effect such that the potential barrier of the insulation layer is critical. The structure must use an insulation layer with a high dielectric constant, and the surface layer should be flat and dense with few defects. Therefore, the present invention uses a high-density, low-thickness, high-k dielectric insulating layer 108, e.g., made by an atomic layer deposition (ALD), to achieve a light-emitting diode having a good tunneling effect.

In one or more embodiments, the high-dielectric-constant insulation layer 108, made by the atomic layer stacking, may have a thickness ranging from 3 nanometers to 8 nanometers, but not being limited thereto.

In one or more embodiments, the high-dielectric-constant insulation layer 108 may have a thickness less than 15 nanometers in order to achieve a possible tunneling effect, but not being limited thereto.

Compared with a conventional light-emitting diode device, a section of the current distribution layer 110, with which the metallic electrode 112 is aligned, does not have a current block material inside thereof. Instead, the high-dielectric-constant insulation layer 108 underneath enable the current distribution layer 110 to achieve the uniform diffusion of electrons flowing or electric current.

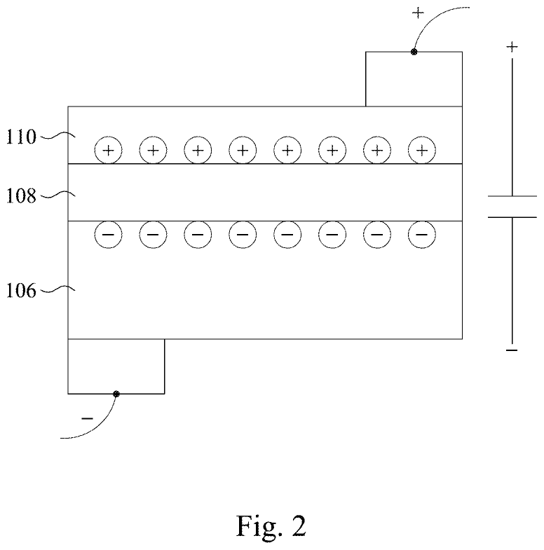

Reference is made to FIG. 2, illustrating a schematic view showing an operation principle of the light-emitting diode device of FIG. 1 at a low bias voltage. When the current distribution layer 110 is applied with an electric voltage, i.e., a bias voltage applied between the metallic electrodes 112 and 114, smaller than a turn-on threshold voltage of the light-emitting layer, i.e., a threshold voltage to turn the light-emitting diode device into a light-emitting state, the tunneling effect does not occur yet. Therefore, the current distribution layer 110, the high-dielectric-constant insulation layer 108 and the second-type semiconductor layer 106 collectively form a capacitor in this state without the tunneling effect.

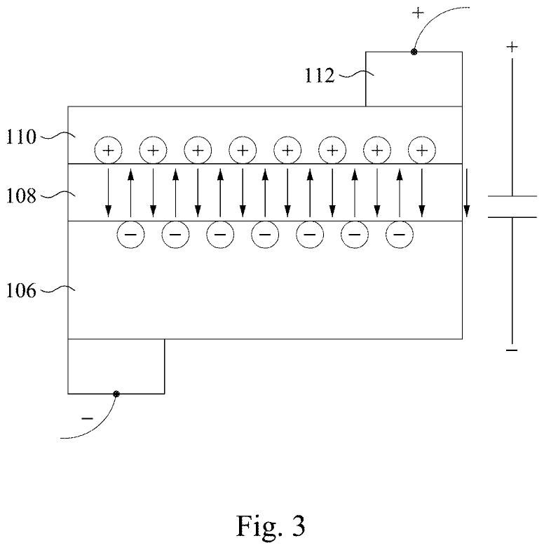

Reference is made to FIG. 3, illustrating a schematic view showing an operation principle of the light-emitting diode device of FIG. 1 at a high bias voltage. When the current distribution layer 110 is applied with an electric voltage, i.e., a bias voltage applied between the metallic electrodes 112 and 114, greater than a turn-on threshold voltage of the light-emitting layer, i.e., a threshold voltage to turn the light-emitting diode device into a light-emitting state, the tunneling effect occurs on the high-dielectric-constant insulation layer 108 enables the current distribution layer 110 to achieve the uniform diffusion of electrons flowing or electric current.

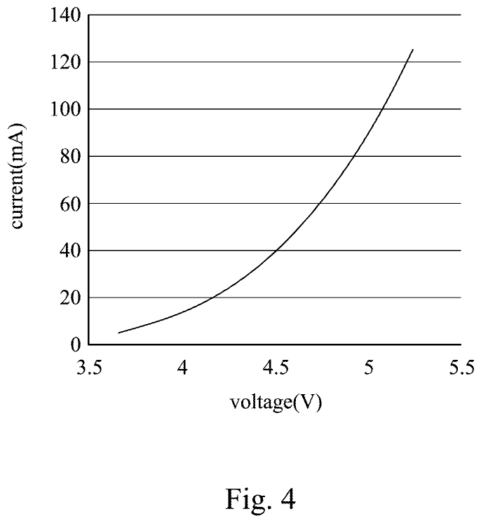

Reference is made to FIG. 4, illustrating a current-voltage diagram of the light-emitting diode device of FIG. 1 at a high bias voltage. When the current distribution layer 110 is applied with an electric voltage greater than a turn-on threshold voltage of the light-emitting layer and the tunneling effect occurs on the high-dielectric-constant insulation layer 108, an electric current (I) applied to the metallic electrode is in a nonlinear or curve relationship with an electric voltage (V) applied to the metallic electrode as illustrated in this Figure.

The electric current (I) and electric voltage (V) applied to the metallic electrode substantially satisfies the following equation:

$$I = exp [ {( c Δ {x}^{2} V - c Δ {x}^{2} E )}^{1 / 2} ] c = \frac{128 {π}^{2} {m}^{*}}{9 {h}^{2}}$$

wherein Δx represents a thickness of the high-dielectric-constant insulation layer 108; E represents the dielectric barrier potential of the high-dielectric-constant insulation layer 108; m* represents the effective mass of the carrier including electron effect mass ˜0.2 m₀ and hole effect mass ˜0.8 m₀ (m₀=9.11×10⁻³¹ kg); h represents Plank constant (6.626×10⁻³⁴ m² kg/s).

The key to realize the present invention is the quality of the high-dielectric-constant insulation layer. The poor quality of the insulation layer (too many defects or insufficient flatness) is highly likely to cause negative effects (such as leakage current). The selection of the insulation layers is also one of the key points. According to the Schrödinger tunneling probability equation (such as the simplified mathematical formula as illustrated above), in case the dielectric insulation effect is not good enough, e.g., the dielectric constant is not greater than a certain value, the leakage current may also be caused. If the insulation layer is too thick, the tunneling rate will be too low to turn the LED into a light-emitting state.

It should be noted that although the thickness of the high-dielectric-constant insulation layer has a better range, the thickness range of the high-dielectric-constant insulation layer is still variable due to the size of the light emitting diode element (or the area of the light emitting surface of the light emitting diode element), the materials of high-dielectric-constant insulation layer and/or the voltage bias to be applied to the high-dielectric-constant insulation layer. Even if the materials of the high-dielectric-constant insulation layer are the same, the high-dielectric-constant insulation layer of different thickness is still variable depending upon the size of the light emitting diode element. Therefore, even for a certain high dielectric constant insulating material, it is difficult to determine an absolute thickness range for the high-dielectric-constant insulation layer.

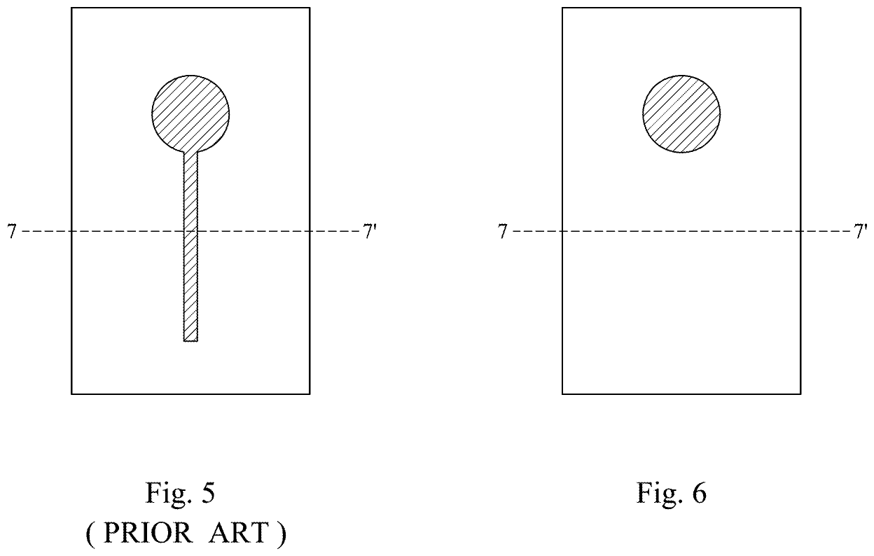

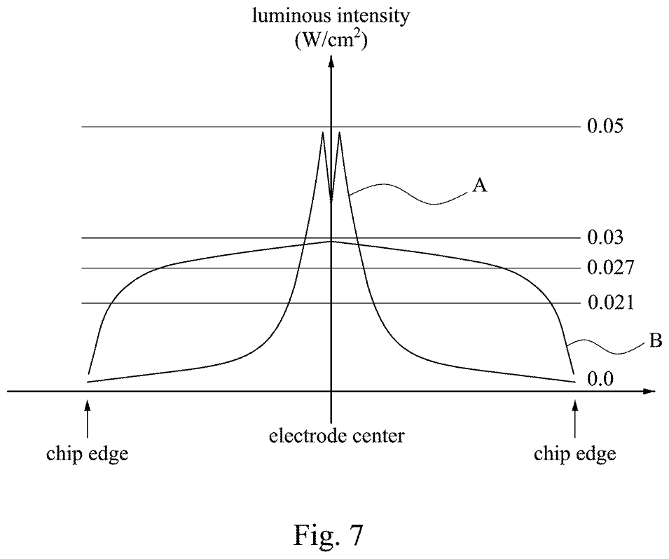

Reference is made to FIGS. 5, 6 and 7. FIG. 5 illustrates a top view of an electrode of a conventional light-emitting diode device; FIG. 6 illustrates a top view of an electrode of a light-emitting diode device according to one embodiment of the present disclosure; and FIG. 7 illustrates a luminous intensity distribution diagram along a line 7-7′ of the light-emitting diode devices in FIGS. 5 and 6.

In order to demonstrate the luminous uniformity of the finger-extension of the present invention, the conventional light-emitting diode device equipped with an electrode having a finger-extension as illustrated in FIG. 5 serves as a comparison embodiment. The light-emitting diode device of the present invention has an electrode without a finger-extension as in illustrated in FIG. 6. Applying same voltages and currents to the light-emitting diode devices equipped with electrodes as illustrated in FIGS. 5 and 6, and respectively measuring the luminous intensity along the line 7-7′ which are illustrated in FIG. 7. The light-emitting diode device of the present invention is, for example, equipped with the features as discussed in embodiments of FIGS. 1-4 and 6.

Reference is made to FIG. 7, the luminous intensity curve A is the luminous intensity measured along the line 7-7′ in FIG. 5 while the luminous intensity curve B is the luminous intensity measured along the line 7-7′ in FIG. 6. As shown in the luminous intensity curve A, even if the convention light-emitting diode has an electrode with the finger-extension, the luminous intensity distribution is dropped rapidly from 0.05 (W/cm²) at the center of the electrode to the chip edges on both sides. As shown in the luminous intensity curve B, even equipped with the electrode without the finger-extension, the luminous intensity distribution is dropped rapidly from 0.03 (W/cm²) at the center of the electrode to 0.021 (W/cm²) at the chip edges on both sides. That is, a maximum difference of the luminous intensity output except the metallic electrode is smaller than 30% ([0.03−0.021]/0.03=30%). If the process for manufacturing the light-emitting diode devices is further improved, a maximum difference of the luminous intensity output except the metallic electrode may be controlled to be smaller than 20%.

In sum, the light-emitting diode device of the present invention utilizes the current distribution mechanism achieved by the electron tunneling method. When the low bias voltage is applied, e.g., smaller than a turn-on threshold voltage of the light-emitting layer, electrons are accumulated to form a surface potential. When the high bias voltage is applied, e.g., greater than a turn-on threshold voltage of the light-emitting layer, full planar electrons form tunneling currents through the insulation layer into the semiconductor layers so as to excite light. This method can solve the uneven problem of current diffusion illuminating, and can also reduce the light-shield problems caused by the large areas of electrodes. This electron tunneling mechanism can be applied to grains of different sizes for the different insulation layers, and the different grain sizes only need to change the positional energy barrier condition to achieve the electron tunneling mechanism.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light-emitting diode device comprising:
a first-type semiconductor layer and a second-type semiconductor layer;
a light-emitting layer disposed between the first-type and the second-type semiconductor layers;
a current distribution layer disposed above the second-type semiconductor layer; and
a high-dielectric-constant insulation layer disposed uniformly between the current distribution layer and the second-type semiconductor layer.

2. The light-emitting diode device of claim 1, wherein the high-dielectric-constant insulation layer has a dielectric constant greater than or equal to 4.

3. The light-emitting diode device of claim 1, wherein the high-dielectric-constant insulation layer comprises Al₂O₃, BaTiO₃, TiO₂, HfO₂, La₂O₃ or Pr₂O₃.

4. The light-emitting diode device of claim 1 further comprising a metallic electrode in contact with the current distribution layer, a section of the current distribution layer, with which the metallic electrode is aligned, does not have a current block material.

5. The light-emitting diode device of claim 1, wherein the current distribution layer, the high-dielectric-constant insulation layer and the second-type semiconductor layer collectively form a capacitor when the current distribution layer is applied with an electric voltage smaller than a turn-on threshold voltage of the light-emitting layer.

6. The light-emitting diode device of claim 1 further comprising a metallic electrode in contact with the current distribution layer, an electric current applied to the metallic electrode is in a nonlinear relationship with an electric voltage applied to the metallic electrode when the light-emitting diode device is in a light-emitting state.

7. The light-emitting diode device of claim 1 further comprising a metallic electrode in contact with the current distribution layer, an electric current applied to the metallic electrode is in a curve relationship with an electric voltage applied to the metallic electrode when the light-emitting diode device is in a light-emitting state.

8. The light-emitting diode device of claim 4, wherein a maximum difference of a light-emitting intensity output from the current distribution layer except the metallic electrode is smaller than 30%.

9. The light-emitting diode device of claim 1, wherein the high-dielectric-constant insulation layer has a thickness less than 15 nanometers.

10. The light-emitting diode device of claim 1, wherein the high-dielectric-constant insulation layer has a thickness ranging from 3 nanometers to 8 nanometers.
